(19) United States
(12) Patent Application Publication
(10) Pub. No.: US 2010/0226847 A1
(43) Pub. Date: Sep. 9, 2010

(54) Method for direct, chirality-selective synthesis of semiconducting or metallic single-walled carbon nanotubes

(75) Inventor: Aleksey V. Vasenkov, Huntsville, AL (US)

Correspondence Address: TOMAS FRIEND, LLC, 904 BOB WALLACE AVENUE, SUITE 228, HUNTSVILLE, AL, 35801, US

(73) Assignee: CFD RESEARCH CORPORATION, Huntsville, AL (US)

(21) Appl. No.: 12/398,332

(22) Filed: Mar. 5, 2009

(51) Int. Cl. D01F 9/12; D01F 9/10; C23C 16/00

(52) U.S. Cl. 423/439; 423/447.3; 423/447.2; 118/728; 977/750; 977/748; 977/843

(57) ABSTRACT

The present invention is a method comprising a direct chirality-selective nucleation and synthesis of single-walled carbon nanotubes from carbon-containing gases using catalytic nanoparticles of uniform size heated by ultra-short laser pulses of selected frequency to temperatures sufficient for carbon nanotube nucleation and synthesis.

### BACKGROUND OF THE INVENTION

1. Field of the Invention

The present invention relates to the methods and systems for the chirally-selective synthesis of single-walled carbon nanotubes and, in particular, to the selective growth of metallic or semiconducting single-walled carbon nanotubes.

2. Description of Related Art

Single-walled carbon nanotubes (SWCNTs) are graphitic filaments/whiskers with diameters typically ranging from 0.3 to 10 nm. The attributes of single-walled carbon nanotubes such as extraordinary mechanical strength and superior heat and electrical conductivity are of interest for a wide range of practical applications.

Single-walled carbon nanotubes can be metallic or semiconducting, depending on the way that the graphene sheet of the nanotube wall is rolled up, which is designated by the chiral indices (n,m). Tubes with chiral indices (n, 0) and (n, n) are termed zigzag and armchair, respectively. Metallic tubes occur if difference n−m is divisible by 3; otherwise the tubes are semiconducting. The chirality of the tube also determines other properties such as band gap.

The existing methods of SWCNT synthesis include Arc Discharge, Laser Ablation, and Chemical Vapor Deposition. In the Arc Discharge method, the single-walled carbon nanotubes self-assemble from a carbon vapor produced by an arc discharge sustained between two carbon electrodes, with or without catalyst. In the Laser Ablation approach, a high-power laser beam is applied to a volume of carbon-containing gas (methane, carbon monoxide, etc.), with or without catalytic material, to grow single-walled carbon nanotubes. In the Chemical Vapor Deposition method, carbon-containing feedstock gas is heated to 700° C. and used to deliver a supply of carbon onto a substrate, where a catalytic metal layer promotes the growth of single-walled carbon nanotubes. An important requirement for the growth of single-walled carbon nanotubes is nano-structuring of the catalyst because the diameter of the tube is commensurate with the diameters of the catalyst nanoparticles.

Existing methods of synthesizing single-walled carbon nanotubes are not able to control tube chirality during growth, or whether the nanotube grown will be semiconducting or metallic. While several post-growth sorting methods are known, the manipulation of single-walled carbon nanotubes in any post-growth method is difficult and expensive. Consequently, the cost of purely metallic or purely semiconducting single-walled carbon nanotubes is currently in the range of $1 M per gram. For comparison, multi-walled carbon nanotubes with mixed chirality currently cost only $30 per gram.

U.S. Pat. No. 7,357,983 B2 and U.S. Pat. No. 7,485,279 B2 disclose a method for controlling the electronic properties and diameters of SWCNTs made using vapor deposition. This method is limited, however, to SWCNTs produced on a mesoporous siliceous framework substrate, which is heated to temperatures in excess of 700° C.

The presently disclosed invention fills a need in the art for a method of selectively producing semiconducting and metallic single-walled carbon nanotubes, especially on substrates having melting temperatures below the temperatures required for SWCNT synthesis.

### BRIEF SUMMARY OF THE INVENTION

In one aspect, the present invention is a method for direct chirality-selective nucleation and synthesis of single-walled carbon nanotubes on a transparent substrate comprising catalytic nanoparticles of uniform size distributed on the substrate surface.

In a second aspect, the present invention is an article of manufacture comprising either metallic or semiconducting single-walled carbon nanotubes nucleated and grown directly on a transparent substrate. Such articles of manufacture possess functional properties superior to articles of manufacture in which sorted, preformed SWCNTs are attached to a substrate.

In a third aspect, the invention is an apparatus for the direct nucleation and synthesis of single-walled carbon nanotubes having a selected chirality and diameter.

Catalytic nanoparticles are selectively heated to temperatures sufficient for SCNT growth using a ultra-short laser pulses. This allows the use of a substrate material having melting temperature below 700° C., 500° C., or lower, as long as the substrate material is transparent to the frequency of laser light used. The pulse frequency of the laser is selected to selectively produce metallic or semiconducting SWCNTs.

### BRIEF DESCRIPTION OF THE DRAWINGS

FIG. 1 is a schematic of a reactor for chirality-selective synthesis of semiconducting or metallic single-walled carbon nanotubes.

FIG. 2 is a graph showing the computationally simulated temperature evolution of Ni nanoparticles of uniform size placed onto terephthalate transparent substrates for two test cases.

### DETAILED DESCRIPTION OF THE INVENTION

Definitions:

An ultra-short laser pulse is used herein to describe a light pulse (electromagnetic radiation) produced by the process of stimulated emission with a pulse frequency of from 100 gigahertz (1×10¹¹ Hz) to 10 terahertz (10×10¹² Hz).

The term “transparent substrate” is a material having a transmittance of at least 80% for laser light of the frequency used to selectively heat catalytic nanoparticles according to the present method.

Description of the Method

The present method is based, in part, on the discovery that the chirality of SWCNTs synthesized by the selective pulsed laser heating of metal catalyst nanoparticles can be controlled by adjusting the pulse frequency of the laser.

The present method comprises the steps of:
a) calculating the Radial Breathing Mode frequency of the single-walled carbon nanotubes to be synthesized based on their chirality and diameter;
b) distributing catalytic nanoparticles of uniform size in a pattern onto a transparent substrate having a melting point;
c) placing the transparent substrate into a chemical vapor deposition chamber;
d) flowing a carbon-containing gas over the transparent substrate at a temperature below the melting point of the transparent substrate; and
e) subjecting the transparent substrate to ultra-short frequency laser pulses to heat the catalytic nanoparticles to a temperature of at least 500° C., thereby selectively synthesizing single-walled carbon nanotubes having a selected chirality and diameter on the catalytic nanoparticles, wherein:
the frequency of the ultra-short laser pulses is equal to, or an integral multiple of, the Radial Breathing Mode frequency calculated for the single-walled carbon nanotubes.

Calculating the Radial Breathing Mode (RBM) Frequency SWCNTs:

The RBM frequency of the SWCNTs to be synthesized can be calculated from their chirality and diameter using numerical methods known in the art such as those described by Kürti, J. and V. Zólyomi (2003) Molecular Nanostructures, AIP Conference Proceedings 685, Melville, N.Y., p. 456 and S'anchez-Portal D. et al. (1999) Phys. Rev. B 59:12678, which are incorporated herein in their entirety.

Methods For Fabricating and Patterning Catalytic Nanoparticles:

Catalytic nanoparticles may be fabricated and patterned using methods known in the art including nanoimprint lithography, Lithographically Anchored Nanoparticles Synthesis (LANS), nanomolding, and inverse micelle liquid-based methods. The diameter of nanoparticles used may vary from about 0.3 nm to about 10 nm, depending on the application for which single-walled carbon nanotubes will be synthesized.

Selection of Catalytic Nanoparticle Diameter

The diameter of the catalytic nanoparticles is close to, preferably no more than 20% larger, and more preferably no more than 10% larger than the diameter of the SWCNTs. The diameter is uniform for catalytic nanoparticles, preferably varying by less than 20% and more preferably by less than 10%.

The transparent substrate comprising patterned catalytic nanoparticles is placed inside a chemical vapor deposition reactor chamber. A carbon containing processing gas such as acetylene, carbon monoxide, methane, propane, or butadiene, or combinations thereof, is injected into the chemical vapor deposition chamber at a temperature below the melting point of the substrate. The flow of carbon-containing gas is directed toward the substrate. The catalytic nanoparticles patterned onto the substrate are selectively heated by a laser emitting ultra-short pulses having a frequency equal to or a multiple of the RBM calculated for the desired SWCNT chirality and diameter. The laser pulses do not significantly heat the substrate because the substrate is made from a material that is transparent to the frequency of the laser pulses. Once the temperature of the nanoparticles reaches about 700° C., the growth of well-crystallized SWCNTs begins. If oxygen is used in addition to the carbon-containing gas, the growth of SWCNTs may begin at temperatures as low as 500° C.

The laser pulse frequency, f, is selected to be equal to or an integral multiple of the Radial Breathing Mode (RBM) frequency of growing single-walled carbon nanotubes. This allows the delivery of energy to a catalytic nanoparticle in resonance with the vibration of the single-walled carbon nanotubes to be synthesized. The vibrational frequency forced on the nucleating SWCNTs disrupts or prevents the nucleation of SWCNTs having a RBM different form the SWCNTs to be synthesized. Consequently, only SWCNTs having the desired RBM and corresponding chirality are synthesized. The diameter of single-walled carbon nanotubes synthesized is commensurate with the diameter of the catalyst nanoparticles used for their catalytic growth.

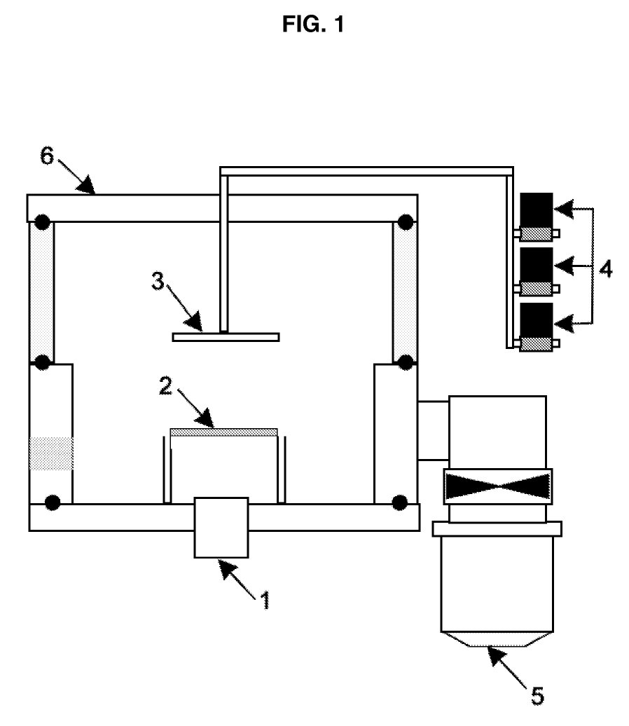

FIG. 1 shows a schematic of a reactor for the chirality-selective synthesis of semiconducting or metallic single-walled carbon nanotubes. Nanoparticles of uniform size made from Ni, Fe, Co, Cu, Al, V, Y, Mo, Pt, Pd and their binary and ternary alloys are uniformly dispersed onto a transparent substrate 2, such as glass or polyethylene terephthalate. The substrate is placed inside a Chemical Vapor Deposition reactor 6, configured to selectively heat the catalytic nanoparticles using a pulse laser 1. A carbon-containing processing gas 4 such as acetylene, carbon monoxide, methane, propane or butadiene is injected through nozzle 3 at room temperature towards the substrate. Laser 1 emits ultra-short pulses to selectively heat the catalytic nanoparticles. Once the temperature of nanoparticles exceeds 700° C., the growth of well-crystallized metallic or semiconducting single-walled carbon nanotubes is initiated, depending on the diameter of nanoparticles and selected frequency of the laser pulses.

A 1-D computational model was used to show that catalytic nanoparticles can be heated by a pulsed laser to temperatures required for single-walled carbon nanotubes synthesis. Neglecting evaporation of nanoparticles and temperature gradients inside nanoparticles, one can write the following differential equation for the temperature evolution of nanoparticle heated by a laser pulse:

$$\frac{\partial T}{\partial t} = \frac{3 {K}_{abs} {Ef}_{0} ( t )}{2 fd ρ C} - \frac{4 {μ}_{s} T}{( s + 1 ) {d}^{2} ρ C} [ {( \frac{T}{Ts} )}^{s + 1} - 1 ] \qquad ( 1 )$$

where K_{abs} is the absorption efficiency coefficient of nanoparticle; E is the energy density of the laser pulse; C and ρ are the specific heat and the density of nanoparticle material, respectively; f₀(t) is the laser pulse shape; s is the power exponent; μₛ is the thermal conductivity of substrate. The first term in Eq. (1) represents the heat generation inside a nanoparticle due to a laser pulse and the second term accounts for the heat losses to the transparent substrate.

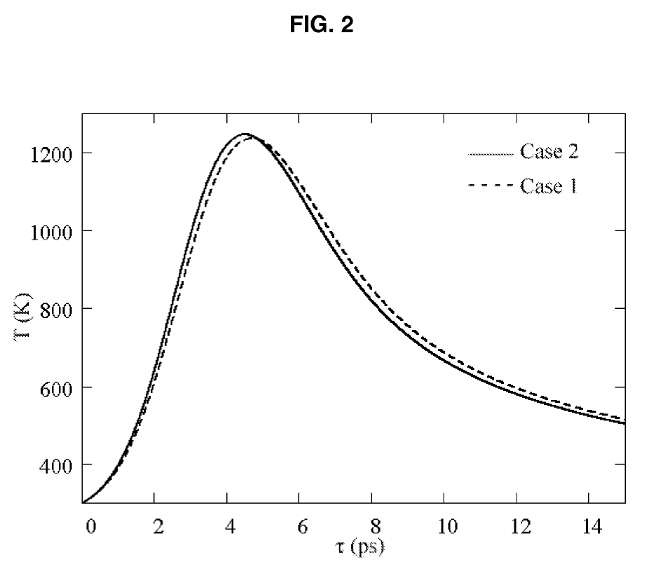

FIG. 2 is a graph showing the computationally simulated temperature evolution of Ni nanoparticles of uniform size placed onto terephthalate transparent substrates for two test cases. In test case 1, the nanoparticles have a diameter of 1.775 nm and the frequency of laser pulses is 0.624 THz, corresponding to f=c₀ω_{RBM}^{S}/2π, where c₀ is the light speed and ω_{RBM}^{S}=232 cm⁻¹ nm/d. In test case 2, the nanoparticles have a diameter of 1.738 nm and the frequency of laser pulses is 0.649 THz, corresponding to f=c₀ω_{RBM}^{M}/2π, ω_{RBM}^{M}=236 cm⁻¹ nm/d.

In both test cases, the absorption efficiency coefficient K_{abs} used was 4. The specific heat and density values for nickel were C=840 J/K kg and ρ=8.9·10⁻³ kg/cm³. The Power exponent was s=1 and the thermal conductivity of the substrate fabricated from transparent polyethylene terephthalate (PET) used was μₛ=0.0024 W/cm K.

What is claimed is:

1. A method for the direct nucleation and synthesis of single-walled carbon nanotubes having a selected chirality and diameter comprising the steps of:
a) calculating the Radial Breathing Mode frequency of the single-walled carbon nanotubes to be synthesized based on their chirality and diameter;
b) distributing catalytic nanoparticles of uniform size in a pattern onto a transparent substrate having a melting point;
c) placing the transparent substrate into a chemical vapor deposition chamber;
d) flowing a carbon-containing gas over the transparent substrate at a temperature below the melting point of the transparent substrate; and
e) subjecting the transparent substrate to ultra-short frequency laser pulses to heat the catalytic nanoparticles to a temperature of at least 500° C., thereby selectively synthesizing single-walled carbon nanotubes having a selected chirality and diameter on the catalytic nanoparticles, wherein:
the frequency of the ultra-short laser pulses is equal to, or an integral multiple of, the Radial Breathing Mode frequency calculated for the single-walled carbon nanotubes.

2. The method of claim 1, wherein the selected chirality of the single-walled carbon nanotubes corresponds to a metallic or semiconducting property.

3. The method of claim 1, wherein the catalytic nanoparticles have a diameter of from about 0.3 nm to about 10 nm.

4. The method of claim 1, wherein the single-walled carbon nanotubes are metallic single-walled carbon nanotubes.

5. The method of claim 1, wherein the single-walled carbon nanotubes are semiconducting single-walled carbon nanotubes.

6. The method of claim 1, wherein the catalytic nanoparticles comprise a transition metal.

7. The method of claim 6, wherein the catalytic nanoparticles comprise a metal selected from the group consisting of Ni, Fe, Co, Cu, Al, V, Y, Mo, Pt, Pd, and their binary and ternary alloys.

8. The method of claim 1, wherein the diameter of single-walled carbon nanotubes and the catalytic nanoparticles have the same diameter plus or minus 20%.

9. The method of claim 1, wherein the single-walled carbon nanotubes are aligned.

10. The method of claim 1, wherein the carbon-containing gas is selected from the group consisting of acetylene, carbon monoxide, methane, propane and butadiene.

11. The method of claim 1, wherein the transparent substrate comprises a glass or a polyethylene terephthalate.

12. An apparatus for the direct nucleation and synthesis of single-walled carbon nanotubes having a selected chirality and diameter comprising:
a chemical vapor deposition chamber;
a transparent substrate comprising uniformly sized catalytic nanoparticles patterned on a surface of the transparent substrate;
a source of carbon-containing gas;
a nozzle configured to flow the carbon-containing gas from the source of carbon-containing gas towards the transparent substrate; and
a pulse laser configured to emit laser pulses in the direction of the transparent substrate with a frequency of from 100 gigahertz to 10 terahertz.

13. An article of manufacture comprising: single-walled carbon nanotubes synthesized directly on catalytic nanoparticles distributed the surface of a transparent substrate, wherein the single-walled carbon nanotubes are either semiconducting single-walled carbon nanotubes or metallic single-walled carbon nanotubes.

14. The article of manufacture recited in claim 13, wherein the single-walled carbon nanotubes are metallic single-walled carbon nanotubes.

15. The article of manufacture recited in claim 13, wherein the single-walled carbon nanotubes are semiconducting single-walled carbon nanotubes.
